(19) United States
(12) Patent Application Publication
(10) Pub. No.: US 2014/0093098 A1
(43) Pub. Date: Apr. 3, 2014

(54) HANDHELD DEVICE AND ELECTRONIC DEVICE ASSEMBLY AND METHOD FOR ADJUSTING VOLUME

(71) Applicant: HON HAI PRECISION INDUSTRY CO., LTD., New Taipei (TW)

(72) Inventors: CHIH-CHUN CHANG, New Taipei (TW); CHIA-WEN CHUANG, New Taipei (TW)

(73) Assignee: HON HAI PRECISION INDUSTRY CO., LTD., New Taipei (TW)

(21) Appl. No.: 14/019,571

(22) Filed: Sep. 6, 2013

(30) Foreign Application Priority Data
Oct. 3, 2012 (TW) 101136428

(51) Int. Cl. H03G 7/00

(52) U.S. Cl. CPC H03G 7/00
USPC 381/105

(57) ABSTRACT

A handheld device communicates with an electronic device. The handheld device includes a setting unit, an audio sampling unit, and a controlling unit. The setting unit is used for setting a standard volume. The audio sampling unit samples a volume of the electronic device. The controlling unit calculates a difference value between the volume of the electronic device sampled by the audio sampling unit and the standard volume, and generates an adjusting signal for adjusting the volume of the electronic device to the standard volume.

### BACKGROUND

1. Technical Field

The present disclosure relates to handheld devices and electronic devices, and particularly to a handheld device and a method for adjusting a volume of an electronic device communicating with the handheld device.

2. Description of Related Art

Different video programs played by an electronic device have different volumes. When a user switches from a first program to a second program, a volume of the second program might be too low to hear clearly, or be too loud. The user has to manually adjust the volume to an appropriate level by a remote control or buttons/keys on the electronic device, which is troublesome.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a block diagram of an electronic device assembly including a handheld device and an electronic device.

FIG. 2 is a flowchart of an adjustment method of the handheld device.

### DETAILED DESCRIPTION

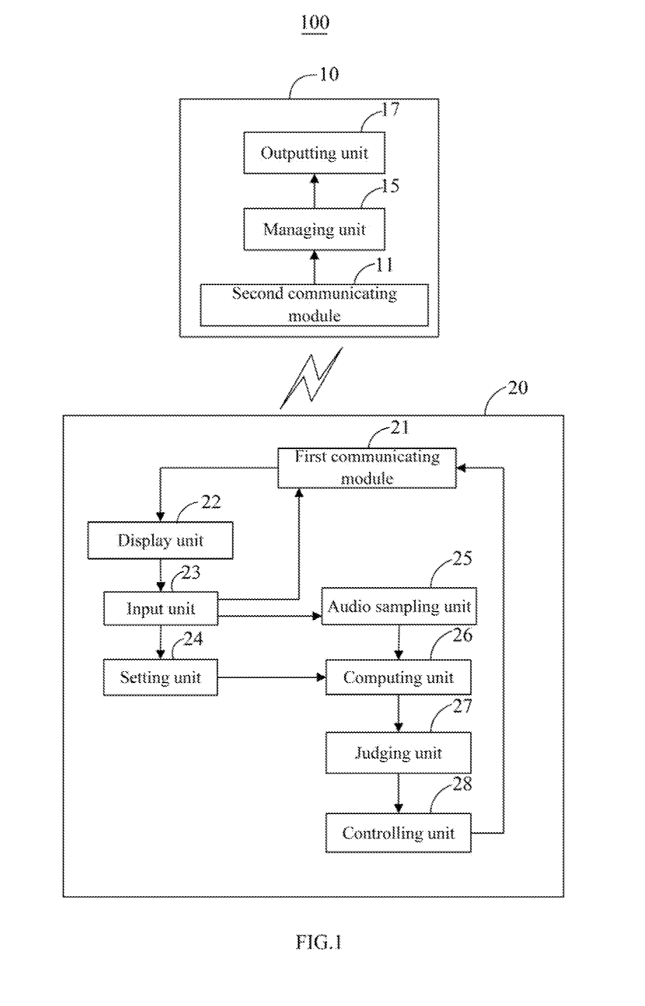

FIG. 1 illustrates an embodiment of an electronic device assembly 100. The electronic device assembly 100 includes an electronic device 10 and a handheld device 20 for controlling the electronic device 10. The electronic device 10 can be a television, a computer, or the like. The electronic device 10 plays programs having audio signals. The handheld device 20 can be a remote control, a mobile phone, a personal digital assistant (PDA), or the like. The handheld device 20 communicates with the electronic device 10 wirelessly, such as by Wireless Fidelity (WI-FI), BLUETOOTH, or infrared. In the embodiment, the electronic device 10 is a television. The handheld device 20 is a mobile phone communicating with the electronic device 10 via WI-FI.

The handheld device 20 includes a first communicating module 21, a display unit 22, an input unit 23, a setting unit 24, an audio sampling unit 25, a computing unit 26, a judging unit 27, and a controlling unit 28. The electronic device 10 includes a second communicating module 11, a managing unit 15, and an outputting unit 17. The second communicating module 11 is configured to communicate with the first communicating module 21. When the first communicating module 21 communicates with the second communicating module 11 in response to operations of a user, the handheld device 20 communicates with the electronic device 10.

The display unit 22 displays information of the handheld device 20, such as pictures or icons.

The input unit 23 can be a number of hard keys or soft keys located on the handheld device 20. The input unit 23 allows a user to input a volume value.

The setting unit 24 sets the volume value inputted on the input unit 23 by the user as a standard volume and generates switching signals in response to the user's operation. The standard volume can be set according to the current environment and/or requirements of the user. For example, when the user is in a noisy environment, the standard volume can be set to a stronger volume; when the user is in a quiet environment, the standard volume can be set to a weaker volume. The switching signal switches programs. For example, a current first program is switched to a second program. In the embodiment, the first and second programs are TV channels. The managing unit 15 controls the electronic device 10 to switch from the current first program to the second program in response to the switching signal.

The audio sampling unit 25 samples the volume of the second program after the second program replaces the first program in response to the switching signal. The audio sampling unit 25 samples the volume of the second program at a predetermined frequency for a predetermined time period. For example, the audio sampling unit 25 samples the output volume of the second program every 2 seconds for 10 seconds.

The computing unit 26 calculates a reference volume according to the sampled volumes of the second program sampled by the audio sampling unit 25. The reference volume is an average value of the volumes of the second program sampled by the audio sampling unit 25 during the predetermined time period.

The judging unit 27 judges whether or not the reference volume is in a predetermined volume range. The predetermined volume range is set by the user and is pre-recorded in the judging unit 27. The predetermined volume range is the standard volume plus or minus 30 decibels (dB). A standard volume of 50 dB is used as an example. When the reference volume is determined to be in the predetermined volume range, the judging unit 27 outputs a managing signal to the controlling unit 28. When the reference volume is determined to be not in the predetermined volume range, the judging unit 27 generates a detecting signal. The audio sampling unit 25 responds to the detecting signal by sampling the volume of the second program again for the predetermined time frequency for the predetermined time period.

When the reference volume is within the predetermined volume range, the controlling unit 28 calculates a difference value by comparing the reference volume and the standard volume in response to the managing signal. The controlling unit 28 generates an adjusting signal for adjusting the volume of the second program to the standard volume when the reference volume is not equal to the standard volume. In the embodiment, the difference value is obtained by deducting the standard volume from the reference volume. When the difference value is a negative value, the managing unit 15 increases the volume of the second program to the standard volume in response to the adjusting signal. When the difference value is a positive value, the managing unit 15 decreases the volume of the second program to the standard volume in response to the adjusting signal. For example, when the reference volume of the second program is 30 dB, the controlling unit 28 generates the adjusting signal to increase the volume of the second program by 20 dB, so that the adjusted volume of the second program is 50 dB.

The audio output unit 17 outputs the audio signals of the second program.

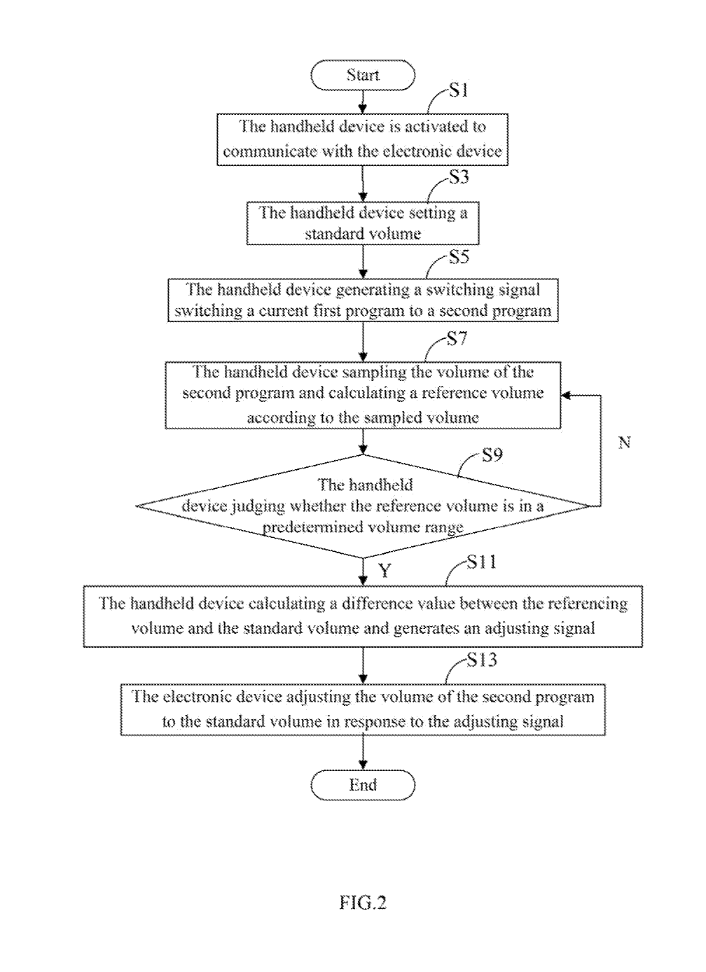

FIG. 2 shows an adjustment method applied to the handheld device 20 for adjusting the volume of the electronic device 10. The adjustment method includes the following steps:

In step S1, the handheld device 20 is activated to communicate with the electronic device 10.

In step S3, the setting unit 24 sets a standard volume inputted by a user. In the embodiment, the standard volume is set according to the need of the user or the environment where the electronic device 10 is located.

In step S5, the input unit 23 generates a switching signal in response to the operation of the user. The switching signal is executed to switch programs. The managing unit 15 controls the electronic device 10 to switch from the current first program to the second program in response to the switching signal.

In step S7, the audio sampling unit 25 samples the volume of the second program and calculates a reference volume according to the sampled volume. In the embodiment, the reference volume is an average value of the volume of the second program sampled by the audio sampling unit 25 during a predetermined time period.

In step S9, the judging unit 27 judges whether or not the reference volume is in a predetermined volume range. If the reference volume is in the predetermined volume range, step S11 is implemented. If the reference volume is out of the predetermined volume range, the process goes to step S7.

In step S11, the controlling unit 28 calculates a difference value between the reference volume and the standard volume, and generates an adjusting signal. In the embodiment, the difference value is the difference between the reference volume and the standard volume. When the difference value is a negative value, the electronic device 10 increases the volume of the second program to the standard volume in response to the adjusting signal. When the difference value is a positive value, the electronic device 10 decreases the volume of the second program to the standard volume in response to the adjusting signal.

In step S13, the computing unit 15 adjusts the volume of the second program to the standard volume in response to the adjusting signal.

Although information and the advantages of the present embodiments have been set forth in the foregoing description, together with details of the structures and functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. A handheld device capable of communicating with an electronic device, the handheld device comprising:
a setting unit for setting a standard volume;
an audio sampling unit for sampling the volume of the electronic device; and
a controlling unit for computing a difference value between the sampled volume of the electronic device and the standard volume, and generating an adjusting signal for adjusting the volume of the electronic device to the standard volume when the sampled volume is not equal to the standard volume.

2. The handheld device as claimed in claim 1, wherein when the electronic device is switched from a current first program to a second program, the audio sampling unit is controlled to sampled the volume of the second program.

3. The handheld device as claimed in claim 2, wherein the sampling unit samples the volume of the second program at a predetermined frequency for a predetermined time period.

4. The handheld device as claimed in claim 3, further comprising a computing unit for calculating a reference volume according to the sampled volume of the second program.

5. The handheld device as claimed in claim 4, wherein the reference volume is an average value of the sampled volume of the second program.

6. The handheld device as claimed in claim 5, wherein the difference value is obtained by comparing the reference volume relative to the standard volume.

7. The handheld device as claimed in claim 1, further comprising a judging unit for judging whether the reference volume is in a predetermined volume range; wherein when the reference volume is determined to be in the predetermined volume range, the judging unit outputs a managing signal to the controlling unit for allowing the computing unit to calculate the difference value to adjust the volume of the second program to the standard volume.

8. The handheld device as claimed in claim 7, wherein when the reference volume is determined to be out of the predetermined volume range, the judging unit outputs a detecting signal to the audio sampling unit for allowing the audio sampling unit to further sample the volume of the second program at the predetermined frequency for the predetermined time period.

9. An electronic device assembly, comprising:
an electronic device capable of outputting an audio signal; and
a handheld device communicating with the electronic device; the electronic device comprising:
a setting unit for setting a standard volume;
an audio sampling unit for sampling the volume of the audio signal of the electronic device; and
a controlling unit for computing a difference value between the sampled volume of the electronic device and the standard volume, and generating an adjusting signal for adjusting the volume of the electronic device to the standard volume when the sampled volume is not equal to the standard volume.

10. The electronic device assembly as claimed in claim 9, wherein when the electronic device is switched from a current first program to a second program, the audio sampling unit is controlled to sampled the volume of the second program.

11. The electronic device assembly as claimed in claim 10, wherein the sampling unit samples the volume of the second program at a predetermined frequency for a predetermined time period.

12. The electronic device assembly as claimed in claim 11, wherein the handheld device further comprising a computing unit for calculating a reference volume according to the sampled volume of the second program.

13. The electronic device assembly as claimed in claim 12, wherein the reference volume is an average value of the sampled volume of the second program.

14. The electronic device assembly as claimed in claim 13, wherein the difference value is obtained by comparing the reference volume relative to the standard volume.

15. The electronic device assembly as claimed in claim 9, wherein the handheld device further comprising a judging unit for judging whether the reference volume is in a predetermined volume range; wherein when the reference volume is determined to be in the predetermined volume range, the judging unit outputs a managing signal to the controlling unit for allowing the computing unit to calculate the difference value to adjust the volume of the second program to the standard volume.

16. The electronic device assembly as claimed in claim 15, wherein when the reference volume is determined to be out of the predetermined volume range, the judging unit outputs a detecting signal to the audio sampling unit for allowing the audio sampling unit to further sample the volume of the second program at the predetermined frequency for the predetermined time period.

17. An adjusting method for adjusting the volume of an electronic device, comprising:
setting a standard volume;
sampling the volume of the electronic device; and
computing a difference value between the sampled volume of the electronic device and the standard volume, and adjusting the volume of the electronic device when the difference value is not zero.

18. The adjusting method as claimed in claim 17, wherein when the electronic device is switched from a current first program to a second program, calculating a reference volume according to the sampled volume of the second program in a time interval at a predetermined period, the reference volume is an average value of the sampled volume.

19. The adjusting method as claimed in claim 17, wherein the difference value is obtained by comparing the reference volume relative to the standard volume.

20. The adjusting method as claimed in claim 17, wherein after sampling a reference volume, the step of the adjusting method further comprising:
judging whether the reference volume is in a predetermined volume range; when the reference volume is determined to be in the predetermined volume range, calculating the difference value to adjust the volume of the second program to the standard volume; when the reference volume is determined to be out of the predetermined volume scale, sampling the volume of the second program at the predetermined frequency for the predetermined time period.
